(19) United States
(12) Patent Application Publication
(10) Pub. No.: US 2026/0003012 A1
(43) Pub. Date: Jan. 1, 2026

(54) ELECTRICAL ASSET MAINTENANCE BASED ON PROBABILITY OF FAILURE

(71) Applicant: Eaton Intelligent Power Limited, Dublin (IE)

(72) Inventors: Bibhudatta Patnaik, Bhubaneswar (IN); Mugdha Vyankatesh Limaye, Nigdi Pune (IN); Prasad Arvind Venikar, Pune (IN); Travis Vernon Spoone, Greenwood, SC (US); Mark Andre Faulkner, Greenwood, SC (US); Antonio Romero Oruga, Greenwood, SC (US)

(21) Appl. No.: 19/241,924

(22) Filed: Jun. 18, 2025

(30) Foreign Application Priority Data
Jun. 27, 2024 (IN) 202411049361

(51) Int. Cl. G01R 31/40

(52) U.S. Cl. CPC G01R 31/40

(57) ABSTRACT

A monitoring system including: a connection interface configured to couple to an electrical asset; and a probability of failure module configured to: access a health index of the electrical asset; determine a probability of failure of the electrical asset based on the health index of the electrical asset; access scores, the scores including a score for each of at least two parameters associated with the electrical asset; determine a probability of failure of the at least two parameters associated with the electrical asset based on the scores; and determine a contribution of the at least two parameters to the probability of failure of the electrical asset based on the probability of failure of the at least two parameters.

### CROSS-REFERENCE TO RELATED APPLICATION

This application claims priority to Indian patent application Ser. No. 202411049361, filed Jun. 27, 2024 and titled ELECTRICAL ASSET MAINTENANCE BASED ON PROBABILITY OF FAILURE, which is incorporated herein by reference in its entirety.

### TECHNICAL FIELD

This disclosure relates to electrical asset maintenance based on probability of failure.

### BACKGROUND

An electrical asset, such as transformer, may be used as part of an electrical system that distributes time-varying or alternating current (AC) electrical power. The electrical system may include other electrical assets, such as, for example, voltage regulators, inductors, transmission lines, and switches.

### SUMMARY

In one aspect, a monitoring system including: a connection interface configured to couple to an electrical asset; and a probability of failure module configured to: access a health index of the electrical asset; determine a probability of failure of the electrical asset based on the health index of the electrical asset; access scores, the scores including a score for each of at least two parameters associated with the electrical asset; determine a probability of failure of the at least two parameters associated with the electrical asset based on the scores; and determine a contribution of the at least two parameters to the probability of failure of the electrical asset based on the probability of failure of the at least two parameters.

Implementations may include one or more of the following features.

The probability of failure module also may be configured to identify one or more of the at least two parameters as an identified contributing parameter that contributes to the probability of failure of the electrical asset. The probability of failure module also may be configured to determine a probability of failure of one or more sub-parameters associated with the identified contributing parameter. The probability of failure module also may be configured to identify at least one of the one or more sub-parameters as an identified contributing sub-parameter that contributes to the probability of failure of the identified contributing parameter. The probability of failure module also may be configured to identify one or more components associated with the identified contributing sub-parameter as being ready for maintenance based on a failure rate of the one or more components. The probability of failure module also may be configured to issue a maintenance advisory for the one or more components identified as being ready for maintenance.

The monitoring system also may include a visualization module.

At least a portion of the probability of failure module may be implemented in a cloud network.

In another aspect, a failure analysis module for a monitoring system includes: a connection interface configured to access information related to an electrical asset, the information including a health index of the electrical asset; and a probability of failure module configured to determine a probability of failure of the electrical asset based on the health index of the electrical asset.

Implementations may include one or more of the following features.

The failure analysis module also may include a visualization module configured to present the probability of failure. The connection interface may be configured to access information related to at least two electrical assets, the information including a health index of each of the at least two electrical assets; and the probability of failure module may be configured to determine the probability of failure of each of the at least two electrical assets.

In another aspect, an apparatus includes: a monitoring system configured to communicate with electrical assets; and a probability of failure module configured to: access a health index of the electrical assets; and determine a probability of failure of the electrical assets based on a health indexes of the electrical assets.

Implementations may include one or more of the following features.

The monitoring system may be configured to communicate with at least one transformer.

The monitoring system may be configured to communicate with at least one transformer, at least one circuit breaker, and at least one motor.

The electrical assets may be in a fleet; and the probability of failure module may be further configured to: determine a ranking of the electrical assets in the fleet based on the probability of failure; and generate a maintenance schedule for the fleet based on the ranking.

In another aspect, a machine-implemented method includes: accessing a health index of at least one electrical asset; determining a probability of failure of the electrical asset based on the health index of the at least one electrical asset; accessing scores, the scores including a score for each of at least two parameters associated with the at least one electrical asset; determining a probability of failure of the at least two parameters associated with the at least one electrical asset based on the scores; and determining a contribution of the at least two parameters to the probability of failure of the at least one electrical asset based on the probability of failure of the at least two parameters.

Implementations may include one or more of the following features.

Determining the contribution of the at least two parameters to the probability of failure of the at least one electrical asset may include comparing the probability of failure of each of the at least two parameters to a threshold; and any parameter having a probability of failure that exceeds the threshold may be a contributing parameter. The method also may include: associating each contributing parameter with one or more components of the at least one electrical asset; accessing a failure rate of each of the one or more components; and determining whether any of the one or more components of the at least one electrical asset requires maintenance based on the failure rate. Moreover, if any of the one or more components of the at least one electrical asset require maintenance, a maintenance plan may be presented.

In some implementations, the at least one electrical asset includes more than one electrical asset in a fleet, and the method also includes: ranking each electrical asset in the fleet based on the probability of failure of the electrical asset; and determining a maintenance plan for the fleet based on the ranking.

Implementations of any of the techniques described herein may be a system, a method, or executable instructions stored on a machine-readable medium. The details of one or more implementations are set forth in the accompanying drawings and the description below. Other features will be apparent from the description and drawings, and from the claims.

### DRAWING DESCRIPTION

FIG. 1 is a block diagram of an electrical power distribution system that includes an electrical asset and a monitoring system.

FIG. 2 shows another power distribution system that includes another electrical asset and another monitoring system.

FIG. 3 is a flowchart of a process for determining the probability of failure of an electrical asset.

FIGS. 4A and 4B show probability of failure as a function of health index.

FIG. 5 shows an example of a failure analysis visualization.

### DETAILED DESCRIPTION

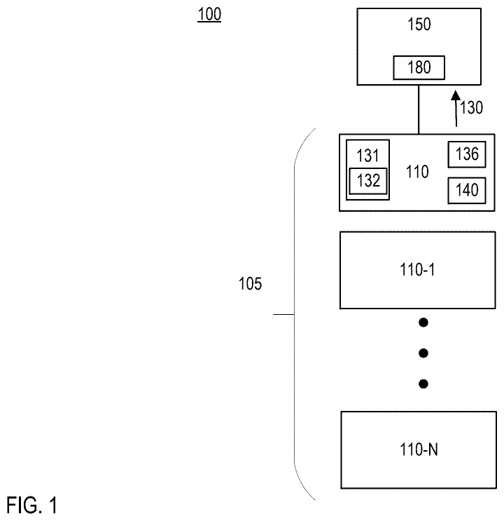

FIG. 1 is a block diagram of an electrical power distribution system 100 that includes an electrical asset 110 and a monitoring system 150. The monitoring system 150 includes a probability of failure (PoF) module 180 that determines the probability that the electrical asset 110 will fail before reaching the end of its expected lifetime. The PoF module 180 facilitates reliability-based maintenance and improves the performance and reliability of the electrical power distribution system 100.

The electrical asset 110 is any type of device or machine that uses electricity. For example, the electrical asset 110 may be a transformer, a circuit breaker, a motor, a voltage regulator, or a switchgear, just to name a few. The electrical asset 110 is associated with sub-parameters 132 and parameters 131, each of which may be associated with a score 136. The electrical asset 110 is also associated with a health index (HI) 140. The HI of the electrical asset 110 is a numerical value that indicates the overall health of the electrical asset 110. Lower values of HI indicate poor health, and higher values of HI indicate good health. For example, HI values may range from 0 to 1, with 0 being the worst health and 1 being the best health. The HI 140 may be determined in any manner.

The HI 140 and the scores 136 may be derived from data 130 or may be determined or assessed as part of a separate process and provided directly in the data 130. The data 130 includes any data related to the electrical asset 110. The data 130 may include, for example, on-line data collected during operation of the electrical asset 110, off-line data collected while the electrical asset 110 is not in operation, modeled data, simulated data, maintenance data, information provided by the manufacturer of the electrical asset 110 (such as nameplate information), test data, and environmental data. The data 130 also may include metrics, which include any measurable or quantifiable property related to the electrical asset 110.

Sudden failure of the electrical asset 110 causes challenges such as, for example, unexpected power outages and unplanned repairs, both of which may lead to more downtime and expenses than planned outages and planned maintenance. Moreover, sudden failure of the electrical asset 110 may damage the electrical asset 110, components of the electrical asset 110, and/or other apparatuses in or near the system 100. The PoF module 180 facilitates observation and monitoring of the health of the electrical asset 110 over time so that maintenance and/or outages may be planned ahead of time.

As discussed below, the PoF module 180 determines the probability of failure of the electrical asset 110 based on the HI 140. Although the HI 140 is a measure of the health of the electrical asset 110, the probability of failure provides a more refined metric for predicting failure than the HI 140 provides alone. Moreover, the PoF module 180 estimates the probability of failure of the electrical asset 110 as a function of the HI 140 and may be calculated once or sporadically during use of the electrical asset 110. This is more efficient and consumes fewer resources than an approach that constantly monitors and updates the HI 140. The probability of failure also provides a reliability-based metric for the electrical asset 110. Thus, the PoF module 180 allows for more precise maintenance scheduling and planning.

Additionally, the PoF module 180 may be used to determine the likely cause(s) of a high probability of failure of the electrical asset 110 by identifying the parameters 131 and/or sub-parameters 132 that contribute most significantly to the probability of failure of the electrical asset 110. For example, the PoF module 180 may include a functional failure analysis (FFA) and/or fault tree analysis (FTA) that can be used to define the probability of failure of various parameters 131 and/or sub-parameters 132, thereby identifying the parameters 131 and/or sub-parameters 132 that are the largest contributors to the probability of failure of the asset 110. By identifying specific parameters 131 and/or sub-parameters 132 that contribute to probability of failure, the monitoring system 150 enables maintenance to be targeted at the components associated with the identified parameters 131 and/or sub-parameters 132. As compared to general maintenance, targeted maintenance may be less expensive and less time intensive. Furthermore, the targeted maintenance helps to reduce or eliminate unexpected failure of the electrical asset 110.

Moreover, the monitoring system 150 and PoF module 180 may be used to monitor a fleet 105 that includes the electrical asset 110 and electrical assets 110-1 to 110-N. For example, the PoF module 180 may be used to determine the probability of failure for each electrical asset in the fleet 105 and to set an appropriate maintenance plan for the fleet 105 that prioritizes maintenance of those electrical assets that have the highest probability of failure. In this way, the monitoring system 150 encourages efficient use of resources and improves the maintenance process while also reducing or eliminating unexpected failures within the fleet 105.

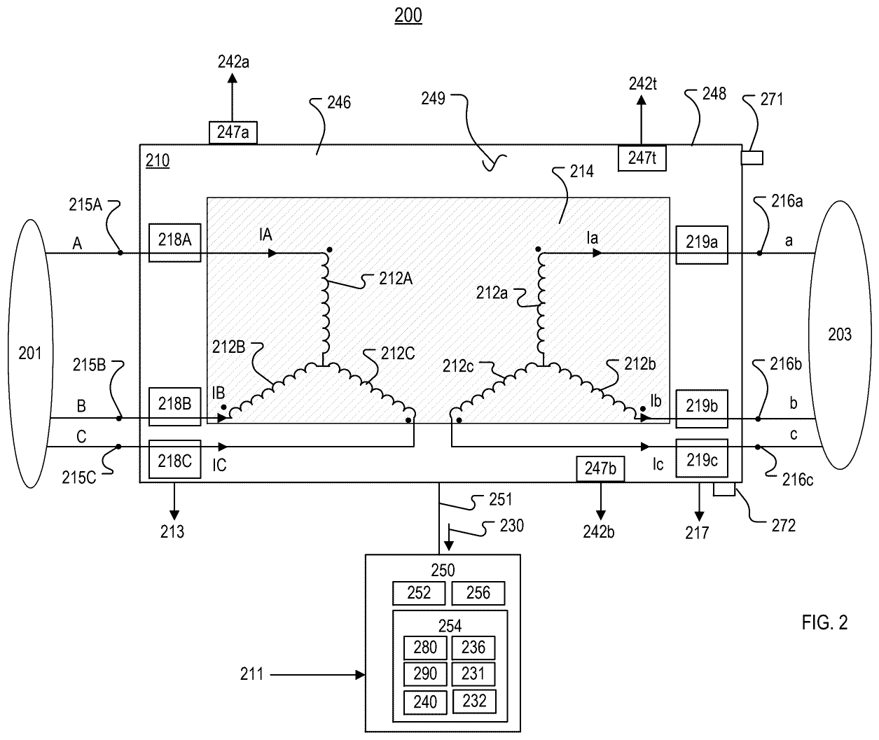

As discussed above, the electrical asset 110 may be a transformer. FIG. 2 shows an example of a power distribution system 200 that includes an electrical asset 210 (a transformer 210). The transformer 210 is a three-phase, wye-wye connected transformer that is cooled with a fluid 246, such as, for example, a synthetic or natural oil. Other configurations of the transformer 210 are possible. For example, the transformer 210 may be configured as a delta-wye transformer.

The transformer 210 is coupled to a monitoring system 250 via a connection 251. The connection 251 is any type of connection that can send data, signals, and/or commands between the transformer 210 and the monitoring system 250. The connection 251 may be, for example, an electrical cable. The monitoring system 250 may be integrated into the transformer 210 such that the monitoring system 250 and the transformer 210 are a single device or package. In some implementations, the monitoring system 250 is separate from the transformer 210. Moreover, the monitoring system 250 may be remote from the transformer 210. For example, the monitoring system 250 and transformer 210 may be separated by kilometers or meters but coupled by the connection 251.

The transformer 210 includes a housing 248 that defines an interior region 249. The interior region 249 contains the fluid 246. The transformer 210 also includes a fluid inlet 271 and a fluid outlet 272, both of which are in fluid communication with the interior region 249. The fluid 246 is intentionally introduced into the interior region 249 through the fluid inlet 271 and is intentionally removed from the interior region 249 through the fluid outlet 272.

The transformer 210 includes a thermal sensors 247t, 247b in the interior region 249. The thermal sensors 247t and 247b may be any type of thermal sensor, such as, for example, a thermocouple. The thermal sensor 247t produces a top fluid temperature indication 242t, which is an indication of the temperature of the fluid 246 at or near the inlet 271. The thermal sensor 247b produces an indication of the temperature of the fluid at or near the outlet 272.

A thermal sensor 247a is positioned to measure the ambient temperature in the environment that is exterior to the interior region 249. For example, the thermal sensor 247a may be mounted on the housing 248 or next to the exterior of the housing 248. In some implementations, the thermal sensor 247a is placed in the vicinity of the housing 248. For example, the thermal sensor 247a may be positioned one (1) meter or more from the exterior of the housing 248. The thermal sensor 247a produces an ambient temperature indication 242b, which is an indication of the temperature of the environment that surrounds the transformer 210. The thermal sensor 247a may be any kind of sensor that is capable of measuring temperature. For example, the thermal sensor 247a may be a thermocouple or a thermometer. In some implementations, the thermal sensor 247a is part of a weather station that produces meteorological data in addition to providing temperature data.

The transformer 210 includes two windings per phase in the interior region 249, as follows: a primary winding 212A and a secondary winding 212a in the A phase, a primary winding 212B and a secondary winding 212b in the B phase, and a primary winding 212C and a secondary winding 212c in the C phase. The transformer 210 also includes electrical insulation 214 (show in gray diagonal striped shading) that protects the primary and secondary windings. The electrical asset 210 has first nodes 215A, 215B, 215C and second nodes 216a, 216b, 216c.

The first nodes 215A, 215A, 215C are electrically connected to phases A, B, C of an AC power grid 201. The AC power grid 201 distributes AC current that has a fundamental frequency. The second nodes 216a, 216b, 216c are connected to phases a, b, c of a load 203. The AC power grid 201 is a three-phase power grid that operates at a fundamental frequency of, for example, 50 or 60 Hertz (Hz). The power grid 201 includes devices, systems, and components that transfer, distribute, generate, and/or absorb electricity. For example, the power grid 101 may include, without limitation, generators, power plants, electrical substations, transformers, renewable energy sources, transmission lines, reclosers and switchgear, fuses, surge arrestors, combinations of such devices, and any other device used to transfer or distribute electricity. The power grid 201 may be low-voltage (for example, up to 1 kilovolt (kV)), medium-voltage or distribution voltage (for example, between 1 kV and 35 kV), or high-voltage (for example, 35 kV and greater). The power grid 201 may include more than one sub-grid or portion.

The load 203 may be any device that uses, transfers, or distributes electricity in a residential, industrial, or commercial setting, and the load 203 may include more than one device. For example, the load 203 may be a motor, an uninterruptable power supply, or a lighting system. The load 203 may be a device that connects the transformer 210 to another portion of the power grid 201. For example, the load 203 may be a recloser or switchgear, another transformer, or a point of common coupling (PCC) that provides an AC bus for more than one discrete load. The load 203 may include one or more distributed energy resource (DER).

During operational use of the transformer 210, primary AC current IA, IB, IC flows in each respective first node 215A, 215B, 215C. A secondary AC current Ia, Ib, Ic flows from each respective second node 216a, 216b, 216c. The transformer 210 may be used to increase or decrease the amplitude of the secondary currents and voltages relative to the primary currents and voltages. When the number of turns in the primary winding 212A, 212B, 212C is greater than the number of turns in the respective secondary winding 212a, 212b, 212c, the amplitude of the secondary current Ia, Ib, Ic is greater than the amplitude of the respective primary current IA, IB, IC. When the number of turns in the primary winding 212A, 212B, 212C is less than the number of turns in the respective secondary winding 212a, 212b, 212c, the amplitude of the secondary current Ia, Ib, Ic is smaller than the amplitude of the respective primary current IA, IB, IC.

The transformer 210 also includes sensors 218A, 218B, 218C that measure one or more electrical properties at the first nodes 215A, 215B, 215C and sensors 219a, 219b, 219c that measure one or more electrical properties at the second nodes 216a, 216b, 216c. For example, each of the sensors 218A, 218B, 218C, 219a, 219b, 219c may measure current, voltage, and/or power at the respective nodes 215A, 215B, 215C, 216a, 216b, 216c. The sensors 218A, 218B, 218C, 219a, 219b, 219c may be any kind of electrical sensor, for example, current transformers (CTs), Rogowski coils, power meters, and/or potential transformers (PT).

The sensors 218A, 218B, 218C produce an indication 213, and the sensors 219a, 219b, 219c produce an indication 217. The indications 213 and 217 include data that represent measured values. For example, the indications 213 and 217 may include sets of numerical values that are each associated with a time stamp, where each set includes three measured values that represent an instantaneous value of an electrical property at one of the first nodes or one of the second nodes. Although the indications 213 and 217 are shown in the example of FIG. 2, other implementations are possible. For example, in some implementations, each sensor 218A, 218B, 218C, 219a, 219b, 219c produces a separate indication.

The transformer 210 is associated with metrics 230. The metrics 230 include any measurable or quantifiable property related to the transformer 210. The metrics 230 may include data measured during use of the transformer 210, such as the indications 213 and 217, the top fluid temperature indication 242t, the bottom fluid temperature indication 242b, and the ambient temperature indication 242t. The metrics 230 may include other data measured during use of the transformer 210. For example, the metrics 230 may include a measurement of an internal pressure, and/or a level of the fluid 246. The metrics 230 that include data measured during operation of the transformer 210 are provided to the monitoring system 250.

The metrics 230 may include data other than data measured during use of the transformer 210. For example, the metrics 230 may include data that is derived from data measured during use of the transformer 210. Furthermore, the metrics 230 may include test data that is not necessarily obtained during operation of the transformer 210. Examples of test data for the transformer 210 include dissolved gas analysis (DGA), tests for total gas pressure, and testing for furanic compounds (FURAN testing). The metrics 230 also may include outputs of models and/or simulations. The metrics 230 also may include operational information and data, such as an indication of when the transformer 210 was first operated, when the transformer 210 was manufactured, and nameplate information associated with the transformer 210. The metrics 230 also may include maintenance data such as a historical record of previous faults that have occurred in the transformer 210 and/or a historical record of repairs. Furthermore, the metrics 230 may include observations of the transformer 210, such as a visible condition of the transformer 210 as compared to established criteria. Additional information may be included in the metrics 230. For example, the metrics 230 may include cost information including, for example, maintenance cost, replacement cost, and estimated cost associated with failure of the transformer 210.

The monitoring system 250 includes an electronic processing module 252, an electronic storage 254, and an input/output (I/O) interface 256. The electronic processing module 252 includes one or more electronic processors, each of which may be any type of electronic processor and may or may not include a general purpose central processing unit (CPU), a graphics processing unit (GPU), a microcontroller, a field-programmable gate array (FPGA), Complex Programmable Logic Device (CPLD), and/or an application-specific integrated circuit (ASIC).

The electronic storage 254 is any type of electronic memory that is capable of storing data and instructions in the form of computer programs or software, and the electronic storage 254 may include volatile and/or non-volatile components. The electronic storage 254 and the processing module 252 are coupled such that the processing module 252 can access or read data from and write data to the electronic storage 254.

The electronic storage 254 stores information about the transformer 210 and may store at least some of the metrics 230. For example, the electronic storage 254 may store nameplate information 211. The nameplate information 211 may include, for example, the rated temperature of the insulation 214 (or the critical hotspot temperature limit); the rated load of the transformer 210; the number of turns on the windings winding 212A, 212B, 212C, 212a, 212b, 212c; a voltage and/or current rating of the transformer 210; a heat capacity of the material of the windings 212A, 212B, 212C, 212a, 212b, 212c; an identifier or flag that indicates the electrical configuration of the transformer 210; and/or an arrangement of the bushings on the transformer 210. The critical hotspot temperature limit is the highest temperature that the insulation 214 is designed to tolerate. The nameplate information 211 is loaded onto the electronic storage 254 via the I/O interface 256. For example, an operator may enter the nameplate information 211 while the transformer 210 is in the field. In another example, the manufacturer of the transformer 210 may add or edit the nameplate information 211 via the I/O interface 256.

The electronic storage 254 may store other of the metrics 230. For example, the electronic storage 254 may store test results, historical fault data, maintenance data, and operational information and data. Furthermore, the electronic storage 254 may store data that is based on measurements taken during operation of the transformer 210. The metrics 230 may be stored in a database, a collection of data structures, or a lookup table.

The transformer 210 is associated with parameters 231 and sub-parameters 232, and the electronic storage 254 stores information about the parameters 231 and the sub-parameters 232. Each parameter 231 may or may not be associated with one or more sub-parameters. Each sub-parameter 232 is associated with one of the parameters 231. The parameters 231 and sub-parameters 232 are any type of information related to the operation of the transformer 210. For example, the transformer 210 parameters 231 may include a cost parameter that has sub-parameters of maintenance cost, replacement cost, and historical cost. In another example, the transformer 210 parameters 231 may include a modeling parameter that has sub-parameters of electrical model, thermal model, fluid model, and gas model. The information about the parameters 231 and the sub-parameters 232 may include, for example, a name of the parameters 231 and the sub-parameters 232 and the grouping of the sub-parameters 232 with the various parameters 231.

The sub-parameters 232 (and parameters 231 that are not associated with any sub-parameters) are associated with one or more components of the transformer 210. For example, the electrical model sub-parameter is associated with a short circuit in one or more of the windings 212A, 212B, 212C, 212a, 212b, 212c or a load imbalance. The thermal model sub-parameter is associated with overheating of the fluid 246 or a hotspot on one or more of the windings 212A, 212B, 212C, 212a, 212b, 212c. The failure rate associated with the components of the transformer 210 is assigned by the manufacturer or determined by the operator of the transformer 210 and stored on the electronic storage 254.

The electronic storage 254 also stores scores 236 for the parameters 231 and sub-parameters 232. The scores 236 may be based on the metrics 230. For example, the score of the electrical model sub-parameter may be based on a computational model (which may be stored as executable instructions on the electronic storage 254) that uses the top fluid temperature indication 242t, the bottom fluid temperature indication 242b, and some nameplate information 211. The scores 236 also may be directly provided to the monitoring system 250 and stored on the electronic storage 254. For example, an operator of the electrical asset 210 may provide the maintenance cost sub-parameter via the I/O interface 256. In some circumstances, metrics 230 or other information may be unavailable for one or more the parameters 231 and/or the sub-parameters 232. In these instances, the scores 236 do not include stores for those parameters 231 and/or sub-parameters 232. In other words, the scores 236 do not necessarily include a score for each parameter 231 and sub-parameter 232.

The electronic storage 254 also stores a health index (HI) 240 for the transformer 210. The HI 240 may be calculated from the metrics 230 or determined separately and provided directly to the monitoring system 250. In implementations in which the HI 240 is determined from the metric 230, the electronic storage 254 includes executable instructions to determine the HI 240. The HI 240 may be a single numerical value or a collection of numerical values, each associated with a particular time (for example, hour, day, week, or month).

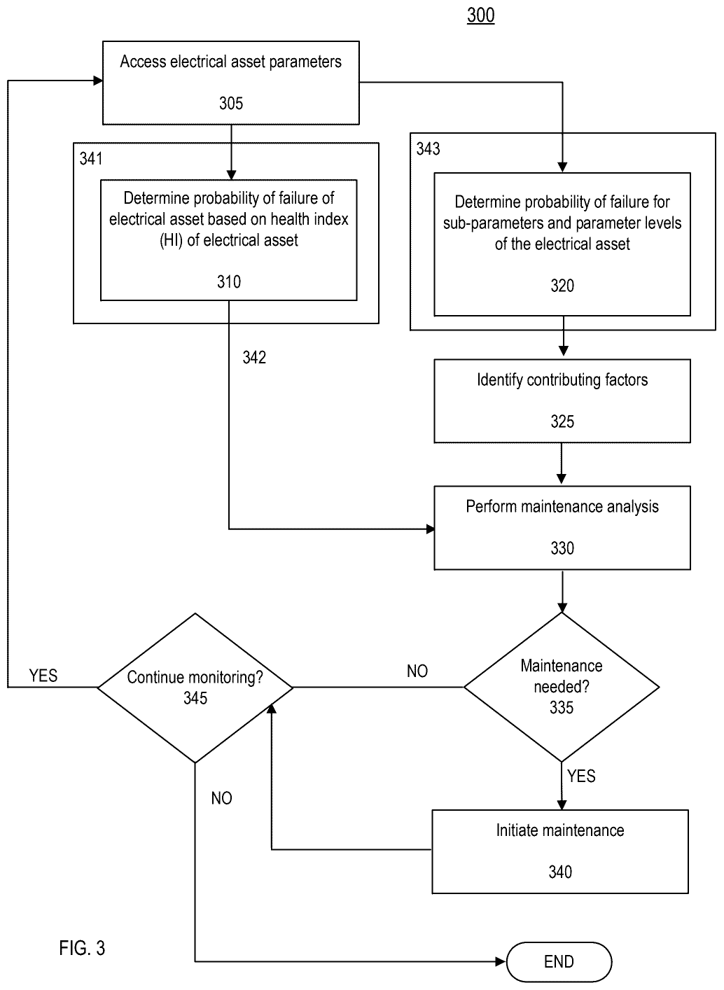

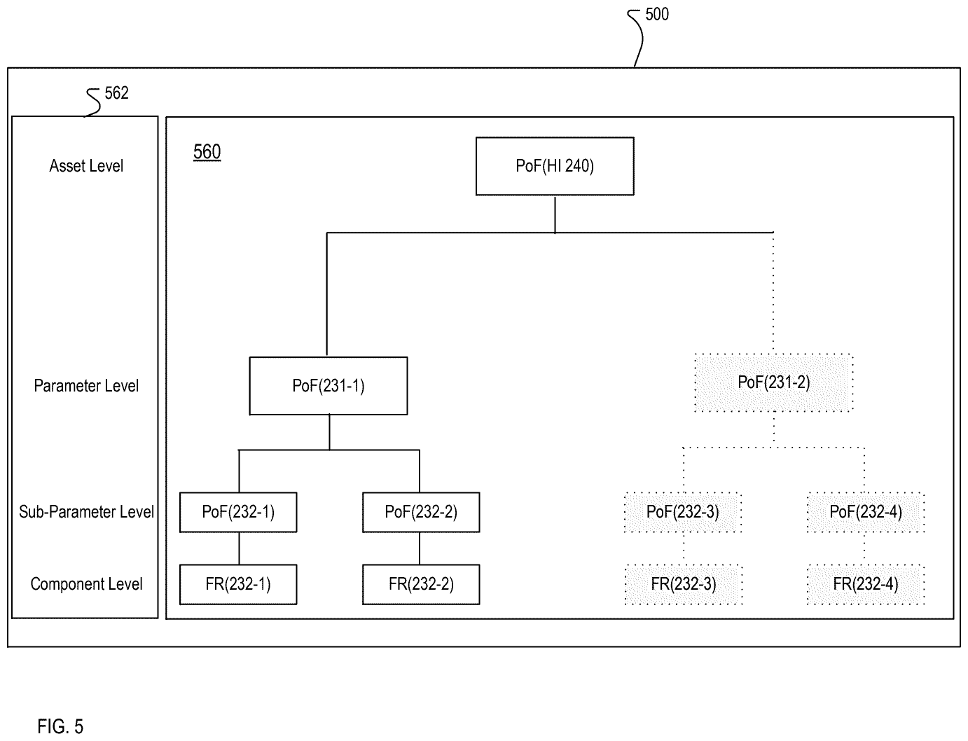

The electronic storage 254 also stores executable instructions that cause the processing module 252 to perform various operations. The executable instructions may be stored in the form of, for example, a computer program, logic, or software. For example, the electronic storage 254 includes executable instructions that implement the PoF module 280 and a visualization module 290. The operation of the PoF module 280 and the visualization module 290 are discussed with respect to FIGS. 3 and 5.

The I/O interface 256 is any interface that allows a human operator, another electronic device, and/or an autonomous process to interact with the monitoring system 250. The I/O interface 256 may include, for example, a display (such as a liquid crystal display (LCD)), a keyboard, audio input and/or output (such as speakers and/or a microphone), visual output (such as lights, light emitting diodes (LED)) that are in addition to or instead of the display, serial or parallel port, a Universal Serial Bus (USB) connection, and/or any type of network interface, such as, for example, Ethernet. The I/O interface 256 also may allow communication without physical contact through, for example, an IEEE 802.11, Bluetooth, or a near-field communication (NFC) connection. The monitoring system 250 may be, for example, operated, configured, modified, or updated through the I/O interface 256.

The I/O interface 256 also may allow the monitoring system 250 to communicate with systems external to and remote from the monitoring system 250 and the transformer 210. For example, the I/O interface 256 may include a communications interface that allows communication between the monitoring system 250 and a remote station (not shown), or between the monitoring system 250 and a separate electrical asset (such as another transformer) using, for example, the Supervisory Control and Data Acquisition (SCADA) protocol or another services protocol, such as Secure Shell (SSH) or the Hypertext Transfer Protocol (HTTP). The remote station may be any type of station through which an operator is able to communicate with the monitoring system 250 without making physical contact with the monitoring system 250. For example, the remote station may be a computer-based work station, a smart phone, tablet, or a laptop computer that connects to the monitoring system 250 via a services protocol or a telephone system, or a remote control that connects to the monitoring system 250 via a radio-frequency signal.

The monitoring system 250 may be configured for cloud analytics. For example, in some implementations, the remote station is a public or private cloud network and the monitoring system 250 sends data to and/or receives data from the cloud network. In another example, in some implementations, all or part of the monitoring system 250 is implemented in the cloud network. In these implementations, some or all of the instructions discussed above with respect to the electronic storage 254 and the electronic processing module 252 are stored and/or executed in the cloud network. Regardless of the specific configuration, the monitoring system 250 may communicate information to an external device through the I/O interface 256.

FIG. 3 is a flowchart of a process 300 for determining the probability of failure of an electrical asset, such as the electrical asset 110 or the transformer 210, and determining which parameters and/or sub-parameters contribute to the probability of failure of the transformer 210. The process 300 is discussed with the transformer 210 to provide an example. However, the process 300 may be used to determine the probability of failure of any electrical asset. In the example discussed below, the process 300 is implemented as a collection of executable instructions that form all or part of the PoF module 280 and are stored on the electronic storage 254. The process 300 is performed by the monitoring system 250. For example, the process 300 may be performed by the electronic processing module 252.

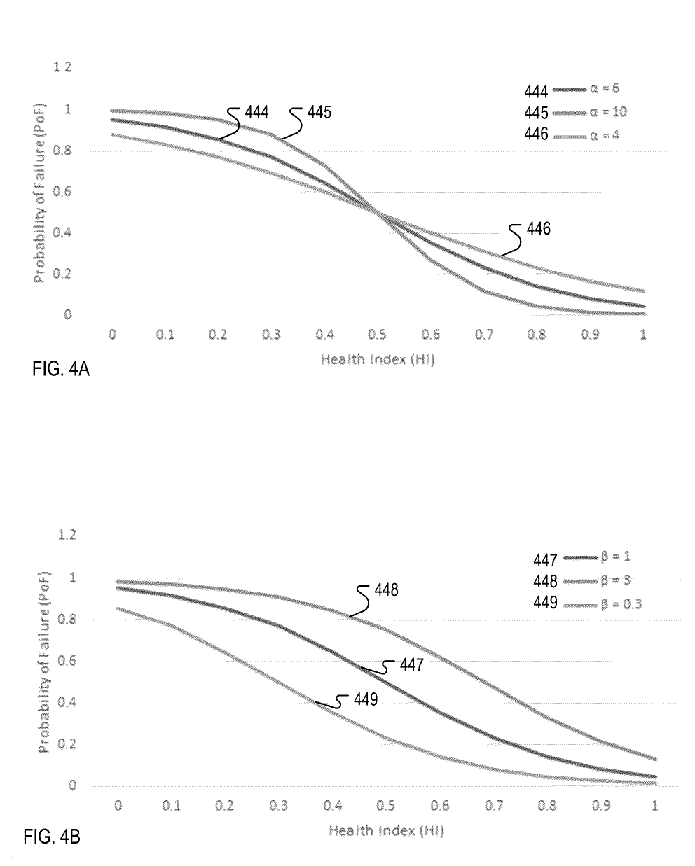

Electrical asset parameters are accessed (305). The parameters include the HI 240 of the transformer 210 and the scores 236 of the parameters 231 and the sub-parameters 232. The process 300 includes a sub-process 341 that determines the probability of failure (PoF) of the transformer 210 based on the HI 240. The probability of failure of the transformer 210 is determined based on Equation (1):

$$P o F ( H I ) = \frac{1}{1 + \frac{{e}^{α ( HI - 0.5 )}}{β}} , \qquad Equation ( 1 )$$

where PoF is a value between 0 and 1, HI is the health index (HI) 240, α is a health index update parameter, and β is a location parameter. The HI is a number between 0 and 1. The parameters α and β are numerical values. The parameters α and β may have any value. For example, α may range from 1 to 10 and β may range from 0.1 to 5. FIG. 4A shows PoF as a function of HI as the health index update parameter (α) is varied between α=4 (curve 446), α=6 (curve 444), and α=10 (curve 445). FIG. 4B shows PoF as a function of HI as the location parameter (β) is varied between β=0.3 (curve 449), β=1 (curve 447), and β=3 (curve 448). The health index update parameter (α) stretches and shrinks the PoF along the y axis, and the location parameter (β) shifts the PoF curve along the y axis with small scale changes. The parameters α and β may be determined experimentally and may be adjusted or tuned by an operator or end user of the transformer 210. For example, the values of parameters α and β may be input to the monitoring system 250 via the I/O interface 256.

Returning to the sub-process 341 in FIG. 3, the value of the HI 240 used in Equation (1) may be determined using any approach. For example, the HI 240 may be determined based on a weighted sum of the parameters 231 and/or sub-parameters 232, with the weights provided by an expert or a technician. In another example, the HI 240 may be determined based on a weighted sum of parameters 231 and/or sub-parameters 232, with the weights being determined based on a pair-wise comparison of rakings provided by a technician or expert. In yet another example, the HI 240 may be determined based on a machine learning technique. In yet another example, the HI 240 may be a value that is provided by the operator or manufacturer of the transformer 210. Regardless of the origin of the value of the HI 240, Equation (1) provides an approach for calculating the probability of failure for the transformer 210 as a function of the HI 240 of the transformer 210. The sub-process 341 outputs the PoF determined using Equation (1) as PoF 342. The PoF 342 is a value between 0 and 1 and/or a percentage between 0% and 100%.

The probability of failure of the parameters 231 and sub-parameters 232 are determined (320) as a function of the scores 236 in a sub-process 343. The sub-process 343 is independent of the sub-process 341 and may be performed before, after, or concurrently with the sub-process 341. In some implementations, the process 300 only includes the sub-process 341.

The probability of failure for one of the parameters 231 or sub-parameters 232 is determined using Equation (2):

$$PoF ( score ) = \frac{1}{1 + \frac{{e}^{α ( s c o r e - 0.5 )}}{β}} , \qquad Equation ( 2 )$$

where PoF is a value between 0 and 1, score is the score of the particular parameter 231 or sub-parameter 232, α is the health index update parameter, and β is the location parameter. The value of the score may be, for example, between 0 and 4 or between 1 and 5. Other ranges are possible. Furthermore, Equation (2) is the same as Equation (1) except the score of a parameter 231 or a sub-parameter 232 is used instead of the HI 240. The parameters α and β are the same as discussed above with respect to Equation (1).

Equation (2) may be used to determine a probability of failure for all of the parameters 231 and sub-parameters 232 that have a score. In some implementations, the operator of the transformer 210 identifies certain parameters 231 and/or sub-parameters 232 for use in a maintenance review. In these implementations, the operator may identify the parameters and/or sub-parameters to use in the review through the I/O interface 256. Moreover, in these implementations, the probability of failure is determined based on Equation (2) only for those parameters and/or sub-parameters identified by the operator.

Factors that contribute to the probability of failure of the transformer 210 are identified (325). The contributing factors may be identified in a top-down approach that allows identification of those sub-parameters 231 (and associated components) lead to the failure of parameters, which can lead to the failure of the transformer 210. By identifying the components that contribute to the probability of failure of the transformer 210, maintenance of the transformer 210 can be efficient, target, and effective, and the incidence of unexpected failure of the transformer 210 is reduced or eliminated.

In the top-down approach, the probability of failure of the parameters 231 determined based on Equation (2) are analyzed first. The parameter having the highest probability of failure is identified as being a contributing parameter. In some implementations, all parameters having a probability of failure above a threshold value are identified as being contributing parameters. Next, the probability of failure of the sub-parameters associated with the contributing parameter or parameters determined based on Equation (2) are reviewed. The sub-parameters having the highest probability of failure are identified as contributing sub-parameters.

Maintenance analysis is performed (330). As discussed above, the sub-parameters 232 (and parameters 231 that do not have sub-parameters) are associated with various components of the transformer 210, and the components have assigned failure rates (FR). A component having a higher failure rate is more likely to fail than a component with a lower failure rate. The failure rates of the component(s) associated with the identified sub-parameters are reviewed. The component having the highest failure rate or the components having a failure rate above a pre-determined threshold are flagged as needing an assessment or maintenance.

In some implementations, a failure analysis visualization is used in the maintenance analysis. FIG. 5 shows an example of a failure analysis visualization 500. The failure analysis visualization 500 is generated by the visualization module 290. The failure analysis visualization 500 includes a PoF section 560 and labels 562 corresponding to Asset Level, Parameter Level, Sub-Parameter Level, and Component Level portions of the PoF section 560.

The Asset Level of the PoF section shows the PoF (HI 240), which is the probability of failure of the transformer 210 as determined by Equation (1). The Asset Level also may display the HI of the transformer 210. The Parameter Level portion shows the probability of failure of each parameter considered in the maintenance analysis. In the example shown in FIG. 5, parameters 231-1 and 231-2 were considered. The probability of failure of the parameter 231-1 and the probability of failure of the parameter 231-2 determined based on Equation (2) are displayed. In the example shown in FIG. 5, the probability of failure of the parameter 231-2 is lower than the probability of failure of the parameter 231-1. As a result, the parameter 231-2 is not identified as a contributing parameter. The probability of failure the parameter 231-2 and its sub-parameters 232-3 and 232-4 and the rate of failure of the components associated with the sub-parameters 232-3 and 232-4 are greyed out to indicate that these elements are not significant contributors to the probability of failure of the transformer 210. The Sub-Parameter Level shows the probability of failure of the sub-parameters 232-1 and 232-2 as determined by Equation (2). The Component Level shows the failure rate (FR) of the components associated with the sub-parameters 232-1 and 232-2.

The failure analysis visualization 500 may be used to identify components for maintenance. For example, if the probability of failure of the sub-parameter 232-1 is greater than the probability of failure of the sub-parameter 232-2, the rates of failure of the components associated with the sub-parameter 232-1 are reviewed for possible maintenance or scheduled for maintenance while the components associated with the sub-parameters 232-2 are not reviewed or scheduled.

Returning to FIG. 3, maintenance is needed (335) if any components are flagged or identified for maintenance in (330). If maintenance is needed, the process 300 proceeds to initiate maintenance (340). Initiating maintenance may include sending an advisory or a message to an operator of the transformer 210 informing the operator that maintenance is needed and listing the component(s) that should be serviced. The advisory or message may include additional information, for example, the probability of failure of the parameters 231 and sub-parameters 232 that were used in the maintenance analysis.

After the maintenance is initiated, or if no maintenance need is identified at (335), the process 300 determines whether to continue monitoring the transformer 210 (345). If the transformer 210 is to be monitored, the process 300 returns to (305) and accesses the electrical asset parameters. If monitoring is no longer needed (for example, if the transformer 210 is being taken out of service), the process 300 ends.

These and other implementations are within the scope of the claims.

What is claimed is:

1. A monitoring system comprising:
a connection interface configured to couple to an electrical asset; and
a probability of failure module configured to:
access a health index of the electrical asset;
determine a probability of failure of the electrical asset based on the health index of the electrical asset;
access scores, the scores comprising a score for each of at least two parameters associated with the electrical asset;
determine a probability of failure of the at least two parameters associated with the electrical asset based on the scores; and
determine a contribution of the at least two parameters to the probability of failure of the electrical asset based on the probability of failure of the at least two parameters.

2. The monitoring system of claim 1, wherein the probability of failure module is further configured to identify one or more of the at least two parameters as an identified contributing parameter that contributes to the probability of failure of the electrical asset.

3. The monitoring system of claim 2, wherein the probability of failure module is further configured to determine a probability of failure of one or more sub-parameters associated with the identified contributing parameter.

4. The monitoring system of claim 3, wherein the probability of failure module is further configured to identify at least one of the one or more sub-parameters as an identified contributing sub-parameter that contributes to the probability of failure of the identified contributing parameter.

5. The monitoring system of claim 4, wherein the probability of failure module is further configured to identify one or more components associated with the identified contributing sub-parameter as being ready for maintenance based on a failure rate of the one or more components.

6. The monitoring system of claim 5, wherein the probability of failure module is further configured to issue a maintenance advisory for the one or more components identified as being ready for maintenance.

7. The monitoring system of claim 1, further comprising a visualization module.

8. The monitoring system of claim 1, wherein at least a portion of the probability of failure module is implemented in a cloud network.

9. A failure analysis module for a monitoring system, the failure analysis module comprising:
a connection interface configured to access information related to an electrical asset, the information comprising a health index of the electrical asset; and
a probability of failure module configured to determine a probability of failure of the electrical asset based on the health index of the electrical asset.

10. The failure analysis module of claim 9, further comprising a visualization module configured to present the probability of failure.

11. The failure analysis module of claim 10, wherein the connection interface is configured to access information related to at least two electrical assets, the information comprising a health index of each of the at least two electrical assets; and the probability of failure module is configured to determine the probability of failure of each of the at least two electrical assets.

12. An apparatus comprising:
a monitoring system configured to communicate with electrical assets; and
a probability of failure module configured to:
access a health index of the electrical assets; and
determine a probability of failure of the electrical assets based on a health indexes of the electrical assets.

13. The apparatus of claim 12, wherein the monitoring system is configured to communicate with at least one transformer.

14. The apparatus of claim 12, wherein the monitoring system is configured to communicate with at least one transformer, at least one circuit breaker, and at least one motor.

15. The apparatus of claim 12, wherein the electrical assets are in a fleet; and the probability of failure module is further configured to:
determine a ranking of the electrical assets in the fleet based on the probability of failure; and
generate a maintenance schedule for the fleet based on the ranking.

16. A machine-implemented method comprising: accessing a health index of at least one electrical asset;
determining a probability of failure of the electrical asset based on the health index of the at least one electrical asset;
accessing scores, the scores comprising a score for each of at least two parameters associated with the at least one electrical asset;
determining a probability of failure of the at least two parameters associated with the at least one electrical asset based on the scores; and
determining a contribution of the at least two parameters to the probability of failure of the at least one electrical asset based on the probability of failure of the at least two parameters.

17. The machine-implemented process of claim 16, wherein determining the contribution of the at least two parameters to the probability of failure of the at least one electrical asset comprises comparing the probability of failure of each of the at least two parameters to a threshold; and any parameter having a probability of failure that exceeds the threshold is a contributing parameter.

18. The machine-implemented process of claim 17, further comprising:
associating each contributing parameter with one or more components of the at least one electrical asset;
accessing a failure rate of each of the one or more components; and
determining whether any of the one or more components of the at least one electrical asset requires maintenance based on the failure rate.

19. The machine-implemented process of claim 18, further comprising:
if any of the one or more components of the at least one electrical asset require maintenance, presenting a maintenance plan.

20. The machine-implemented process of claim 16, wherein the at least one electrical asset comprises more than one electrical asset in a fleet, and further comprising:
ranking each electrical asset in the fleet based on the probability of failure of the electrical asset; and
determining a maintenance plan for the fleet based on the ranking.
